(19) United States
(12) Patent Application Publication
(10) Pub. No.: US 2023/0038222 A1
(43) Pub. Date: Feb. 9, 2023

(54) APPARATUS, SYSTEM AND METHODS FOR BATTERIES

(71) Applicant: 3ME TECHNOLOGY PTY LTD, Sydney, NSW (AU)

(72) Inventor: Steven Robert HOWELL, Sydney, NSW (AU)

(21) Appl. No.: 17/909,076

(22) PCT Filed: Mar. 5, 2021
(86) PCT No.: PCT/AU2021/050194

§ 371 Date: Sep. 2, 2022

(30) Foreign Application Priority Data
Mar. 5, 2020 (AU) 2020900686

(51) Int. Cl. H01M 10/48; H01M 10/42; H01M 50/256; H01M 50/284; H01M 10/44

(52) U.S. Cl. CPC H01M 10/482; H01M 10/425; H01M 10/486; H01M 50/256; H01M 50/284; H01M 10/441; H01M 2010/4271

(57) ABSTRACT

An example of a battery apparatus (10) is provided including: a housing (12) with a connection arrangement (24); a plurality of interoperable battery cartridges (36) removably fittable to the housing (12) to connect with the connection arrangement (24) to form a stack; at least one battery interface arrangement (17) adapted to be removably fitted to the housing (12) to connect with the connection arrangement (24) so as to be in communication with a selection of the plurality of interoperable battery cartridges (26) via the connection arrangement (24). Examples of battery cartridges (36), a system (5) including one or more battery apparatuses (10), and associated example methods are also disclosed.

### RELATED APPLICATIONS

This application claims priority from Australian provisional patent application no. 2020900686 filed on 5 Mar. 2020, the contents of which are incorporated by reference.

### TECHNICAL FIELD

The invention relates to an apparatus, a system and a method for batteries, in particular, an apparatus, a system and a method for the arrangement, handling, management, and operation of banks or arrays of batteries, battery cells or battery cells that may include, but not limited to, rechargeable lithium ion or polymer-based and solid-state batteries.

### BACKGROUND

Banks or arrangements of batteries are used to store electricity and then provide power for both mobile and static energy storage applications, for example, machines and vehicles. A common type of battery bank includes an array of varying rechargeable lithium-based chemistry batteries. Each battery in the bank may be referred to as a cell and each cell includes a wrapped core with metal tabs. Accordingly, to form larger banks of batteries, pluralities of the cells are typically welded together via the tabs to form electrical connections between the cells.

A problem with these types of battery banks include adaptability to different sizes, configurations and capacities, as well as handling and maintenance. Another problem relates to modification or damage to the cells when being connected which may void cell warranty or cause functional issues.

Further problems include the ability to monitor the cells, identify and manage individual cells, and the ability identify at fault cells or conditions that may lead to an unsafe event such as a cell thermal runaway event, and isolate particular cells before the unsafe event occurs. As such, safety remains a significant problem. Further, safe and effective disassembly for both servicing and end of life asset management of these types of battery banks is an issue.

The invention disclosed herein seeks to overcome one or more of the above identified problems or at least provide a useful alternative.

### SUMMARY

In accordance with a first broad aspect there is provided, a battery apparatus including: a housing with a connection arrangement; a plurality of interoperable battery cartridges removably fittable to the housing to connect with the connection arrangement to form a stack, each of the interoperable battery cartridges including at least one battery cell and a battery control and sensor arrangement configured to monitor a condition of the at least one battery cell; at least one battery interface arrangement adapted to be removably fitted to the housing to connect with the connection arrangement so as to be in communication with a selection of the plurality of interoperable battery cartridges via the connection arrangement, the least one battery interface arrangement including an interface control arrangement, and an associated power outlet, wherein the plurality of interoperable battery cartridges each have an associated unique identifier readable by the interface control arrangement to enable the interface control arrangement to operate with each of the selection of the plurality of interoperable battery cartridges to provide power therefrom at the power outlet.

In an aspect, the battery control and sensor arrangement of each of the plurality of interoperable battery cartridges is configured to trigger an error event if the condition indicates an out of condition state.

In another aspect, the error event, a triggered one of the plurality of interoperable battery cartridges is identifiable based on the unique identifier.

In yet another aspect, in the error event, the location of a triggered one of the plurality of interoperable battery cartridges is identifiable.

In yet another aspect, in the trigger event, each triggered one of the plurality of interoperable battery cartridges is configured to isolate itself.

In yet another aspect, the unique identifier is associated with operational conditions of each of the plurality of interoperable battery cartridges, and wherein the interface control arrangement is adapted to monitor the condition of each of the plurality of interoperable battery cartridges and trigger an error event if the condition is outside the operational conditions.

In yet another aspect, in the error event, the interface control arrangement is adapted to isolate each triggered one of the plurality of interoperable battery cartridges.

In yet another aspect, in the error event a contact associated with the interface control arrangement is moved to an open state to isolate triggered ones of the plurality of interoperable battery cartridges.

In yet another aspect, each unique identifier is associated with operating properties of the at least one battery cell of each of the plurality of interoperable battery cartridges.

In yet another aspect, the operating properties include one or more of voltage, temperature, and current.

In yet another aspect, the condition includes one or more of cell temperature, current, voltage and pressure.

In yet another aspect, each of the plurality of interoperable battery cartridges includes a temperature sensor and a current sensor.

In yet another aspect, the connection arrangement includes location identifiers associated with positions within the stack, the location identifiers being readable by the control and sensor arrangement of the plurality of interoperable battery cartridges.

In yet another aspect, the location identifiers provide a location of each of the plurality of interoperable battery cartridges within the stack.

In yet another aspect, each of the plurality of interoperable battery cartridges includes an identification device in communication with the control and sensor arrangement to provide the unique identifier.

In yet another aspect, each of the plurality of interoperable battery cartridges identified by the unique identifier has an associated operational voltage, and the interface control arrangement is configured to read voltages associated with each of the plurality of interoperable battery cartridges and balance each of the plurality of interoperable battery cartridges to the operational voltage.

In yet another aspect the operational voltage is a lower most of the read voltages, with each of the plurality of interoperable battery cartridges being balanced to the lower most of the read voltages.

In yet another aspect, the interface control arrangement is configurable with a pre-determined stack voltage, and is configured to tally the voltage of each of the plurality of interoperable battery cartridges to determine if a read stack voltage is equal to the pre-determined stack voltage.

In yet another aspect, each of the plurality of interoperable battery cartridges includes a printed circuit board on which the control and sensor arrangement is based and the at least one battery cell is located along-side the printed circuit board.

In yet another aspect, the at least one battery interface arrangement includes a printed circuit board in which the interface control arrangement is based.

In yet another aspect, the connection arrangement and plurality of interoperable battery cartridges each include complementary connectors to allow for toolless and cable-free connection thereof.

In yet another aspect, the housing includes a plurality of panels that are configurable and connectable to form an enclosure of a plurality of sizes and shapes in an assembled condition, the housing in the assembled condition having an open side, a base and a top, and the connection arrangement being provided in the form of a connection board being fitted in an orientation between the base and the top of the housing, and spaced apart from the open side so as to define a space in which the plurality of interoperable battery cartridges are insertable.

In yet another aspect, the connection board and the plurality of interoperable battery cartridges are adapted to have a press fit connection thereby allowing toolless and cable-free fitting of the plurality of interoperable battery cartridges.

In yet another aspect, each of the plurality of interoperable battery cartridges includes a board supporting the at least one battery cell, and a handle arranged to allow a user to insert and withdraw each of the plurality of interchangeable battery cartridges from the housing.

In accordance with a second broad aspect there is provided, a system including at least two of the battery apparatus as defined above and herein, the system including at least two of the battery apparatuses in electrical communication so as to form a battery bank.

In accordance with a third broad aspect there is provided, a battery apparatus including: a housing with a connection board, at least one cell carrier board adapted to be removably fitted to the housing to connect with the connection board, the at least one cell carrier board including at least one battery cell and a circuit board with a battery control and sensor arrangement configured to monitor a condition of the at least one battery cell, at least one battery interface board adapted to be removably fitted to the housing to connect with the connection board so as to be in communication with the at least one cell carrier board via the connection board, the battery interface board including an interface circuit board with an interface control arrangement configured to monitor the condition of the at least one battery cell, and an associated power outlet; wherein the battery control and sensor arrangement is configured to trigger isolation of the at least one cell carrier board if the condition indicates a failure state.

In an aspect, the interface control arrangement is configured to monitor the condition of the at least one cell carrier board and trigger isolation of the at least one cell carrier board if the condition indicates the failure state.

In yet another aspect, the condition includes one or more of cell temperature, current, voltage and pressure.

In yet another aspect, the condition includes an identification signal associated with the presence of the at least one carrier cell.

In accordance with a fourth broad aspect there is provided, a cartridge for fitting with a housing to form a battery apparatus, the cartridge including: a metal core printed circuit board with a control and sensor arrangement; at least one battery cell having at least one tab extending therefrom; a clamping arrangement adapted to electrically and thermally connect the at least one tab to the metal core printed circuit board with the at least one battery cell arranged substantially along a face of the metal core printed circuit board; and one or more connectors fitted to the metal core printed circuit board, the one or more connectors being adapted to allow the cartridge to be connected in a toolless manner with a connection board of the housing to provide an electrical connection with the at least one battery cell, a control signal connection with the electronic and sensor arrangement and a thermal connection with the metal core printed circuit board to allow heat transfer therethrough to the connection board of the housing.

In an aspect, the clamping arrangement is adapted to clamp the at least one tab to the metal core printed circuit board such that the at least one tab is not substantially deformed.

In another aspect, the clamping arrangement is adapted to clamp the at least one tab to the metal core printed circuit board without substantially bending the at least one tab.

In yet another aspect, the electronic and sensor arrangement is powered by the at least one battery cell.

In yet another aspect, the cartridge includes at least one plate arranged to sandwich the least one battery cell between the at least one plate and the metal core printed circuit board.

In yet another aspect, the one or more connectors are fitted to an end of the metal core printed circuit board, and wherein the clamping arrangement couples to the metal core printed circuit board toward the end adjacent to the one or more connectors.

In yet another aspect, the at least one battery cell includes a pouch with the at least one tab extending from an end thereof

In yet another aspect, the cartridge includes two battery cells located at opposing faces of the metal core printed circuit board.

In yet another aspect, the cartridge includes two plates, with the two battery cells located being sandwiched between the respective two plates and the metal core printed circuit board.

In yet another aspect, the electronic and sensor arrangement includes a controller adapted to control and monitor the condition of the cartridge.

In yet another aspect, the electronic and sensor arrangement includes one or more condition sensors and wherein the controller is configured to trigger an alert condition based on signals received from the one or condition sensors.

In yet another aspect, in an alert condition, the control is configured to break an electrical connection between the at least one battery cell and the remaining battery apparatus.

In yet another aspect, the one or more condition sensors include one or more of a temperature sensor, a current sensor and a pressure sensor.

In yet another aspect, the cartridge includes an identifier configured to enable to cartridge to be identified upon connection to the battery apparatus.

In yet another aspect, the clamping arrangement includes one or more clamps formed of an electrical and thermally conductive material.

In yet another aspect, an end of the cartridge includes end plate with a handle and the opposing end includes the connector.

In yet another aspect, the connector is a press fit connector.

In yet another aspect, the end plate is adapted to provide a heat sink.

In yet another aspect, the cartridge is immersed in a dielectric fluid to enhance thermal management, reduce corrosion potential and control thermal runaway.

In yet another aspect, the cartridge is rectangularly shaped.

In yet another aspect, the control and sensor arrangement includes at least one of a boost equalisation and a shunt balancing circuit.

In yet another aspect, the control and sensor arrangement includes an indicator arranged to provide a visual indication of the status of the cartridge.

In accordance with a fifth broad aspect there is provided, a method for configuration and forming of a battery bank, the method including the steps of the: Selecting a plurality of battery cartridges, each having at least one battery cell, to provide at least a minimum of a predetermined capacity for the battery bank; Selecting at least one interface cartridge having a power outlet; Forming a housing using a plurality of configurable panels and a configurable connection board so as to be of a size to substantially enclose the selected plurality of battery cartridges; and Fitting the plurality of cell cartridges into the housing such that press fit connectors of the battery cartridges electrically connect with complementary press fit connectors of the connection board thereby forming the battery bank; Fitting the at least one interface cartridge to the housing so as to communicate with each of the plurality of cell cartridges via the connection board to provide an interface between the plurality of cell cartridges and the power outlet; Identifying and confirming the position of each of the plurality of battery cartridges using at least in part a unique identifier thereof; Communicating from each of the plurality of battery cartridges condition information, the condition information including cell voltages associated with each of the identified plurality of battery cartridges; Determining a minimum cell voltage of the cell voltages; and Balancing the plurality of battery cartridges to the minimum cell voltage.

In accordance with a sixth broad aspect there is provided, a method of identifying and isolating an at fault battery cartridge of a battery apparatus, the method including: Monitoring a condition associated with each of a plurality of battery cartridges using a control and sensor arrangement carried by each of the plurality of battery cartridges; Monitoring the condition associated with each of a plurality of battery cartridges at using an interface controller of an interface arrangement in communication with each of the plurality of battery cartridges; Triggering, at least at one of the control and sensor arrangement and the interface controller, an alert state if the condition is outside a predetermined operating condition; Identifying an at fault battery cartridge associated with the alert state; Isolating the at fault battery cartridge.

In accordance with a seventh broad aspect there is provided, a method of efficiently and safely replacing an at fault battery cartridge of a battery apparatus, the method including the steps of: Identifying an at fault battery cartridge associated with an alert state; Removing the at fault battery cartridge from a stack including a plurality of battery cartridges; Replacing the at fault battery cartridge with a new battery cartridge having a voltage lower than each of the remaining plurality of battery cartridges; Identifying the new battery cartridge and its position within the stack; Determining a minimum cell voltage of the cell voltages of each of the plurality of battery cartridges; and Balancing the plurality of battery cartridges to the minimum cell voltage.

In accordance with an eighth broad aspect there is provided, there is provided an apparatus for providing a battery. The apparatus includes a housing, a connection board fitted to the housing, and a plurality of interchangeable battery cartridge adapted to be inserted into the housing so as to form an electrical connection with the connection board in a connected condition thereby forming the battery.

In accordance with a ninth broad aspect there is provided, a cartridge for fitting with a housing to form a battery apparatus, the cartridge including: a board carrying an electronic and sensor arrangement, at least one battery cell having tabs, a clamping arrangement adapted to electrically connect the tabs to the board, and a connector adapted to allow the cartridge to be electrically connected in a cable-free and toolless manner with a connection board of the housing.

In accordance with a tenth broad aspect there is provided, a configurable system for providing a battery bank of various capacities, the system including a configurable housing with a configurable connection board, and a plurality of cartridges each having at least one battery cell adapted to be individually inserted and removed from the housing to connect with the connection board, wherein each of the plurality of cartridges includes an electronic and sensor arrangement configured to provide at least one of a current and a signal to the connection board, and wherein the connection board is adapted to interface with a controller such that an operating status of each individual one of the plurality of cartridges is able to be monitored or determined.

In accordance with a eleventh broad aspect there is provided, a method for configuration and forming of a battery bank, the method including the steps of: selecting a plurality of battery cartridges, each having at least one cell, to provide at least a minimum of a predetermined capacity for the battery bank; forming a housing using a plurality of configurable panels and a configurable connection board so as to be of a size to substantially enclose the selected plurality of battery cartridges; and fitting the plurality of cell cartridges into the housing such that press fit connectors of the battery cartridges electrically connect with complementary press fit connectors of the connection board thereby forming the battery bank.

Further and other broad, as well as more specific aspects are provided below in figures and following description.

### BRIEF DESCRIPTION OF THE FIGURES

The invention is described, by way of non-limiting example only, by reference to the accompanying figures, in which;

FIG. 1 is a perspective view illustrating an example of a system including an apparatus having a housing in which a plurality battery cartridges in the form of cell carrier boards are received and electrically connected;

FIG. 2 is a partial exploded parts view illustrating the housing of the apparatus showing example arrangements of the cell carrier boards;

FIG. 3 is a partial exploded parts view illustrating the housing;

FIG. 4a is a cut away perspective view illustrating the cell carrier boards being fitted to the housing;

FIG. 4b is a side hidden detail view illustrating arrangements of the cell carrier boards being fitted to the housing;

FIG. 5 is a top perspective view illustrating an example of the cell carrier board;

FIG. 6 is a top part curt way view illustrating the carrier board;

FIG. 7 is a side view illustrating the cell carrier board;

FIG. 8a is an exploded parts perspective view illustrating the cell carrier board;

FIG. 8b is a top view illustrating the cell carrier board;

FIG. 9 is a circuit diagram of the cell carrier board;

FIG. 10 is a perspective view illustrating an example of a connection board of the housing;

FIG. 11 is a front view illustrating the connection board of the housing;

FIG. 12 is a side view illustrating the connection board of the housing;

FIG. 13 is an exploded parts view illustrating the connection board of the housing;

FIGS. 14a to 14c illustrate a circuit block diagram of the connection board;

FIG. 15a is a perspective view illustrating the interface arrangement in the form of an interface board or cartridge;

FIG. 15b is another perspective view illustrating an example interface board;

FIGS. 16a and 16b are a fronts view illustrating an example of a front of the interface board;

FIG. 17 is a side view illustrating an example of a front of the interface board;

FIG. 18 is an exploded parts view illustrating an example of a front of the interface board;

FIGS. 19a and 19b illustrate an example circuit diagram illustrating an equalisation circuit carried by a board of the battery arrangement;

FIG. 20a is a perspective part cut away views illustrating a temperature sensor of the battery arrangement;

FIG. 20b is a detailed perspective part cut away view illustrating the temperature sensor of the battery arrangement;

FIG. 21a is a perspective part cut away views illustrating a current sensor of the battery arrangement;

FIG. 21b is a perspective view illustrating a part of the current sensor of the cell carrier board adapted to fit with a tab of the cell;

FIG. 21c is front view illustrating the part of the current sensor; and

FIG. 22 is a functional diagram of the system including the connection board, the interface board and the plurality of cell carrier boards.

### DETAILED DESCRIPTION

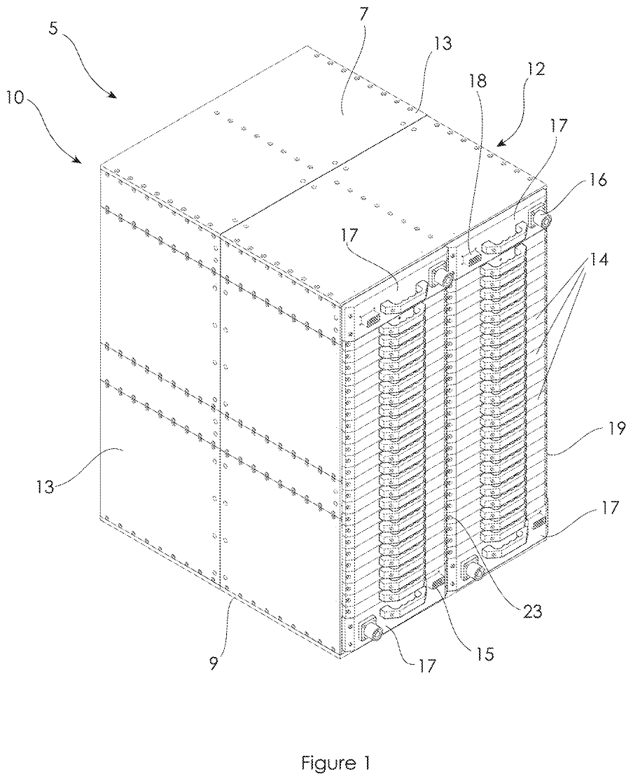

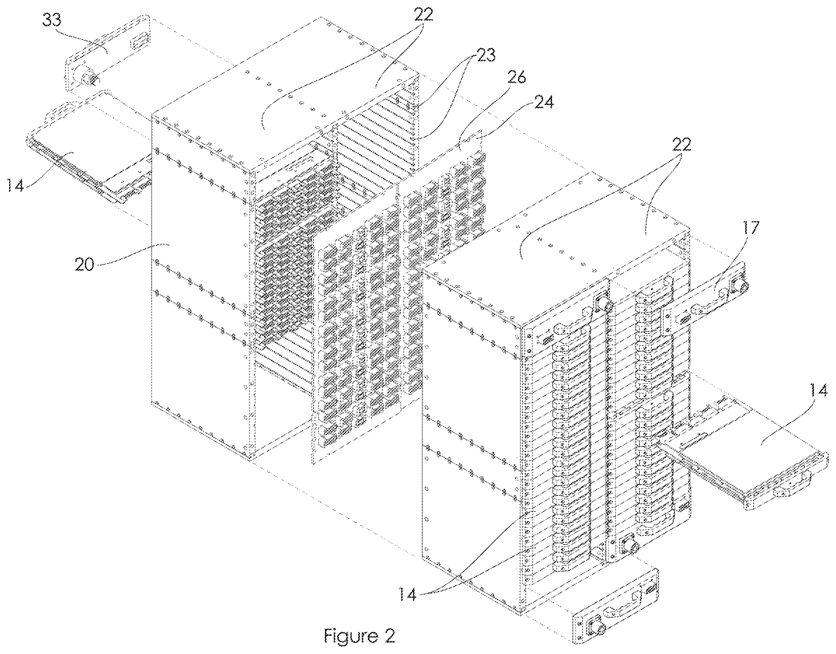

Referring to FIGS. 1 to 5 there is shown a system 5 including a battery apparatus 10 with a housing 12 and a plurality removable of battery arrangements 14, an example of which is shown in FIG. 5 in the form of cell carrier boards 36, are inserted into and supported by the housing 12. The housing 12 being configured to allow the cell carrier boards 36 to be stacked vertically and/or side-by-side and be electrically connected via a connection arrangement 24, shown in FIG. 2. Such an arrangement may be referred to as a “stack” and “bank” of batteries.

The housing 12 includes a top 7, a bottom 9 and sides 13 that define an enclosure 15 with at least one open side 23 in which the cell carrier boards 36 are insertable and removable via handles 19 thereof. Battery interface arrangements or boards 17 are provided toward the top 7 and the bottom 9 of the housing 12 respectively. Each battery interface board 17 includes an electrical connection port 16 and data or control port 18 in communication with the connection arrangement 24 and ultimately each of the cell carrier boards 36.

The housing 12 includes a series of panels 20 and connectors or couplings 21 that are interconnectable to form different sized and shaped versions of the housing 12. The housing 12 may have one, two or more columns of cell carrier boards 36 and, as is the case in this example, may have multiple parallel columns 22 of the cell carrier boards 36 that may be accessible from the opposing sides 23 of the housing 12.

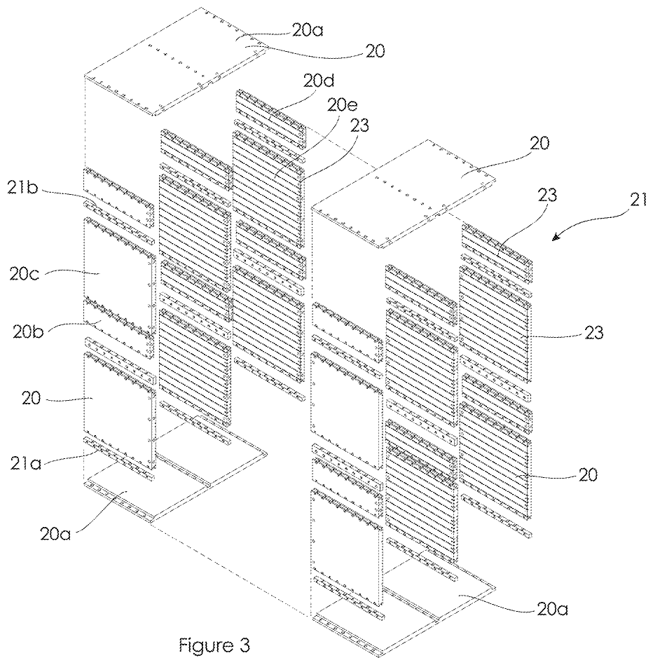

The panels 20 include top/bottom panels 20a, small and large side panels 20b, 20c, and centre small and large panels 20d, 20e, and the connectors 21 may include one sided or double coupling bars 21a, 21b, as best shown in FIG. 3. The series of panels 20 and connectors 21 may include guides 23 in the form of rails or in this example slots that allows the cell carrier boards 36 to be slid into and out of the housing 12.

The series of panels 20 may be formed of a heat conductive material such as aluminium, in this example 20 mm aluminium (but could also include industry application-specific materials such as carbon fibre, composite fibreglass, titanium, polycarbonate or acrylic), that allows the entire apparatus 10 to be filled with a viscous potting compound or oil that can enhance thermal management (both heating and cooling) and support pressurised requirements for applications such as subsea energy storage requirements. The materials may be altered for industry-specific applications and compliance e.g. aluminium, titanium, composite fibreglass, carbon fibre and polycarbonate/acrylic.

As may be best appreciated from FIG. 3, the housing 12 may take many shapes, sizes, forms and configurations depending on the number of the of cell carrier boards 36 which allows the apparatus 10 to be rapidly designed and adapted to different installation situations and power requirements. Prior to assembly, the housing 12 may be substantially flat packed to allow ease of transportation.

The system 5 may include multiples of the apparatus 10 that allows adaption of the capacity, as required. Each apparatus 10 is mechanically designed for maximum performance and safety through a cable free design, integrated fire walls between each cell, integrated thermal management with a high level of monitoring and management. The design enables a flexible modular and scalable battery building block system 5 for suitability in many applications with a high level of serviceability, and provides a high level of safety and visibility. The housing 12 is modular and may adapted to different height, width and depth configurations.

The housing 12 includes a connection arrangement 24 that in this example is provided in the form of a connection board 26 having a plurality of board electrical connectors 28 adapted to electrically connect with the cell carrier boards 36 and data connectors 31. The connection board 26 is arranged such that the plurality of board electrical and data connectors 28, 31 may interface with likewise arranged battery and data connectors 30, 41 of the cell carrier boards 36. The battery interface board 17 may connect to the connection board 26 in a similar manner, and become in connection with the cell carrier boards 36 via the connection board 26.

The connection board 26 allows for different configurations of the cell carrier boards 36 and battery interface boards 17. The connectors 28, 30 may include high current connectors. Other suitable connectors may be utilised, as required.

The connection board 26 may be formed of a heat conductive material such as aluminium to receive heat from the cell carrier boards 36, at least in part via the connectors 28, 30, and may transfer this heat to a further heat sink such as, for example, cooling fins or a cooling water circuit. The suitable connectors are available from Samtec™ and may include a liquid crystal polymer body with metallic connector pins that may be formed of Copper Alloy with Gold plating. Such connectors may be provided as signal/data and power combination or separate connectors may be used.

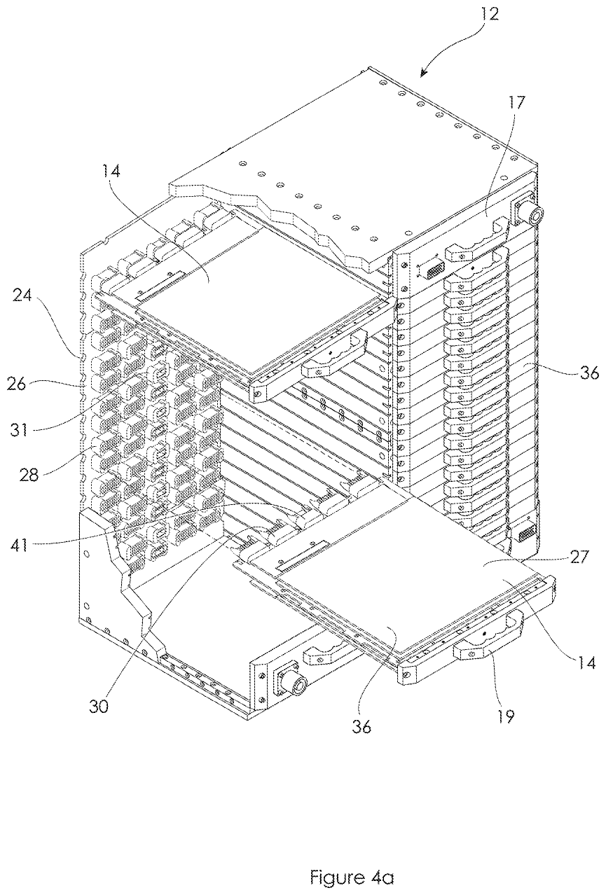

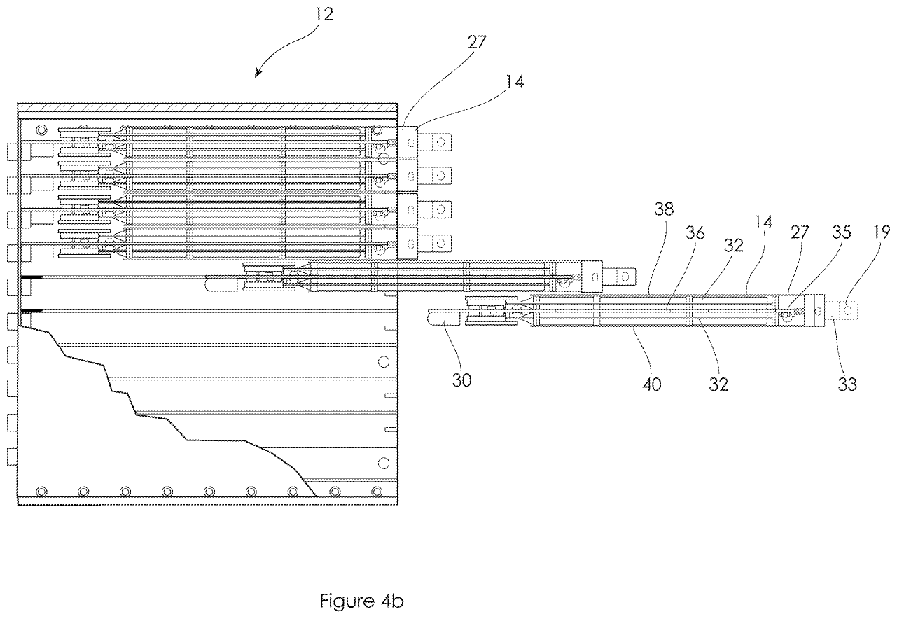

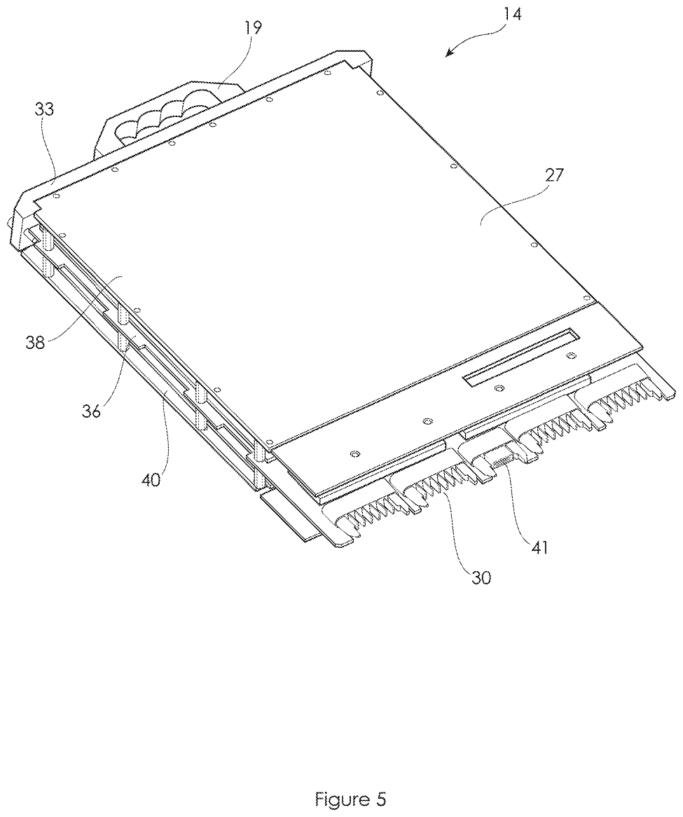

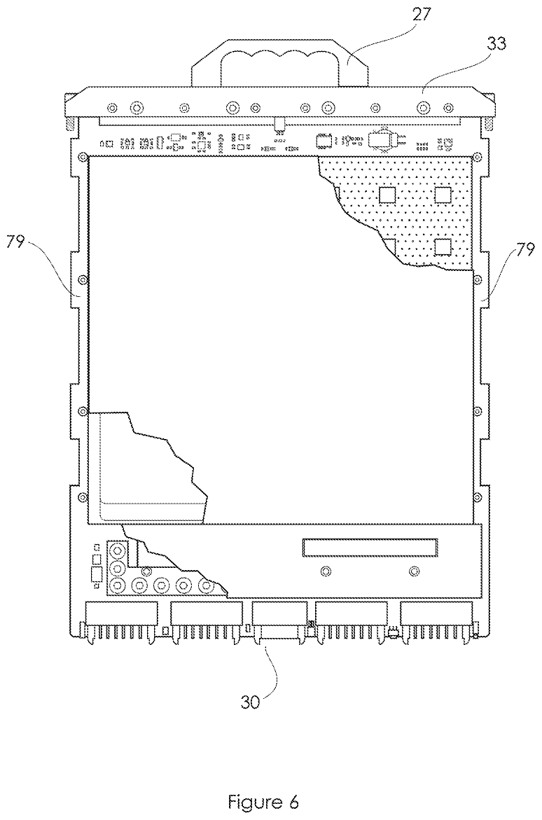

Preferably, as is the case in this example, the connectors 28, 30 and 31, 41 interface via a press or mechanical fit that allows the cell carrier boards 36 to be inserted and removed from the housing 12 in a “plug and play” manner without the need for tools, wire or welding. As may be best appreciated from, for example, FIG. 4b, the cell carrier boards 36 are stacked in the housing 12 and may be slid into and out of respective space 29 of the housing 12 by a user clasping the handle 19.

Accordingly, the cell carrier boards 36 may be considered interchangeable or interoperable battery cartridges 27 that allow for high power connection, via the cable free connections 28, 30, and provide power, sensing, communication and regulation of power as is further detailed below. The “plug and play” cartridge arrangement also provides a modularity, with cell carried boards 36 being able to be added and removed from the housing 12 to alter the capacity of the apparatus 10 and overall system 5.

The connectors 28, 30 are configured for both electrical and signal connection with the electrical connection being ultimately connected a battery or battery cells 32 carried by the cell carrier boards 36. The data connections 31, 41 provide communication with a control and sensor arrangement 34 of the cell carrier boards 36. The connection of the cell carrier boards 36 is such that the status of each cell carrier boards 36 and the cells 32 carried thereby can be determined and this arrangement allows, for example, an at fault cell carrier board 36, and cells 32 thereof, to be identified, then removed and replaced without the need for tools, welding or re-wiring.

Turning now to the battery arrangements 14 in more detail, the battery arrangements 14 are provided in this example the form of cell carrier boards 36 that provide the interoperable battery cartridges 27. Each cell carrier board 36 includes a printed circuit board 37, battery cells 32, and top and bottom plates 38, 40. In this example two battery cells 32 are provided. However, in other examples, there may be a single battery cell 32 or other number of cells, such as four or six battery cells.

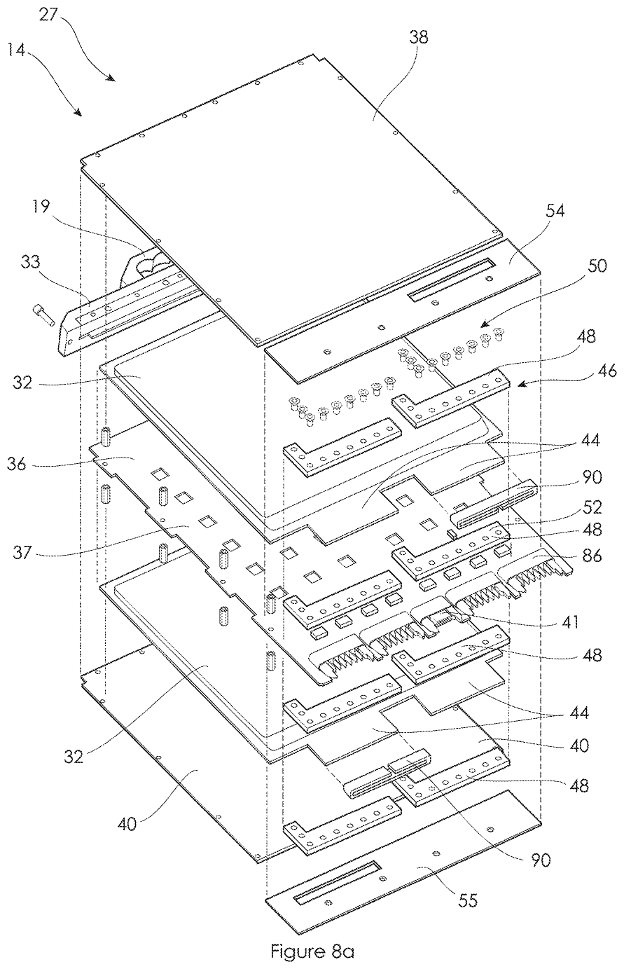

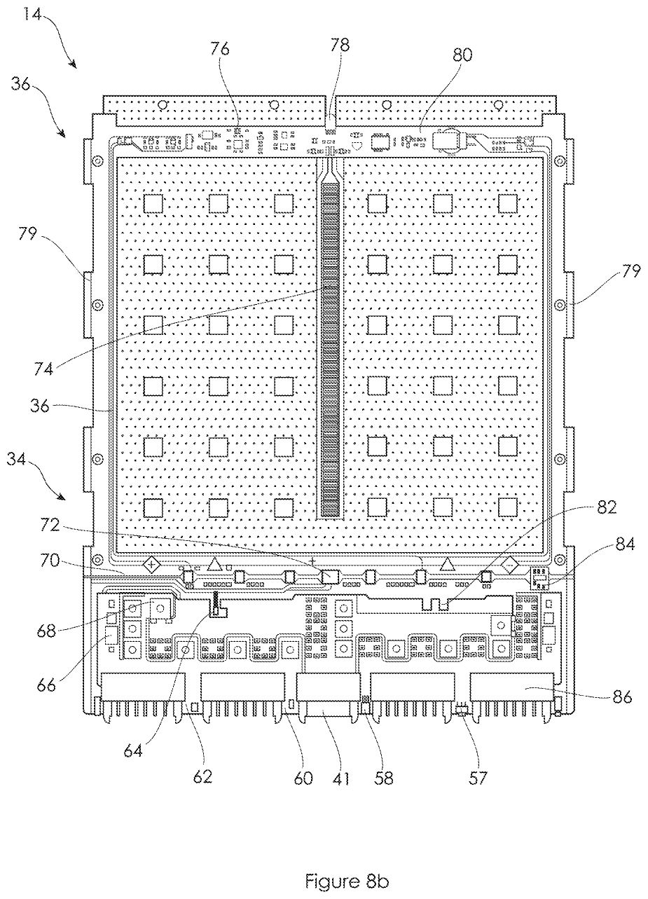

The cell carrier board 36 includes and is based on a printed circuit board 37, as best shown in FIG. 8. The cell carrier board 36 may be configured at assembly for various number of cells to suit desired voltage/amperage. The printed circuit board 37 is preferably a metal core or metal backed printed circuit board 37. The metal core material may be aluminium or copper that functions to assist with heat transfer from the battery cells 32. In this example, the printed circuit board 37 may have four layers of metal copper. The surface finish for the printed circuit board 37 is hot air surface level and the coating is capable of lead-free, lead-based and fluxcore soldering processes. The printed circuit board 37 thickness may be, but not limited to, about 2 mm.

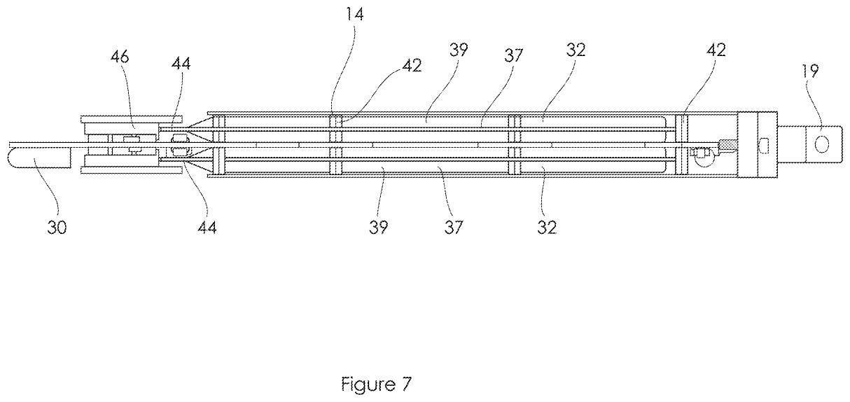

The cell carrier board 36 is secured together by fasteners 42 in a sandwich as best shown in FIG. 7. The top and bottom plates 38, 40 are adjacent to the cells 32 and may be formed of a heat conductive material such as a metal, in this example aluminium, which allows for cooling of the cells 32 by providing a heat sink. The handle 19 is supported by a further heat sink block 33 which supports and is fitted adjacent ends 35 of the cells 32. The heat sink block 33 may also be formed from heat conductive material such as a metal, in this example aluminium.

The battery cells 32 may be rectangularly shaped rechargeable cells using various chemistries and formats (including solid state cells), also known as “battery cells”, with a cell core 45 covered by a pouch 39 and conductive tabs 44 extending from the cell core 45. The cell carrier boards 36 further include a coupling or clamping arrangement 46 arranged to clamp on to the conductive tabs 44 to provide an electrical connection between the tabs 44 and the cell carrier board 36.

More specifically, in this example, the cell carrier board 36 is adapted to house the cells 32 in the form rechargeable cell pouches that may each be, for example, of dimensions 268 mm×265 mm×13 mm. The cell type may include various chemistries such as high energy lithium polymer rechargeable cell with a 3.7V @ 75A power capability, and smaller than or greater than 75 Ah capacities. The design is also capable of integrating solid state battery cells that use solid electrodes and a solid electrolyte as opposed to liquid or polymer gel electrolytes. The design can be scaled up to house larger dimensions and power capacity configurations. For example, the cells 32 may be of a range of Amp Hour per cell capabilities, e.g. 10-20 Ah, 20-50 Ah, 50-100 Ah, and over 100 Ah+ with advancements in energy density;

Referring more specifically now to FIG. 8a, the coupling or clamping arrangement 46 includes upper and lower conductive clamping members 48, 49 that are secured with fasteners 50 to likewise clamping members 52, 53 of the cell carrier board 36, and enclosed by upper and lower end cover plates 54, 55. The clamping arrangement 46 thereby providing a mechanical connection that is electrically conductive with the conductive tabs 44 without needing any wires or welding.

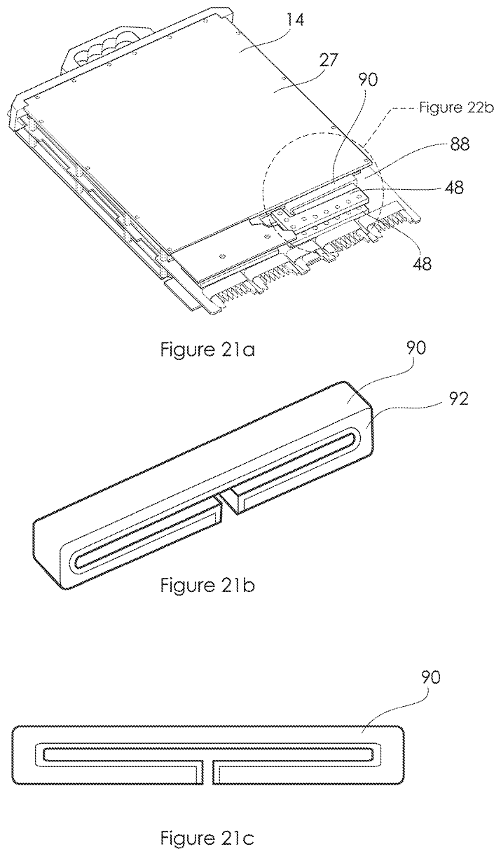

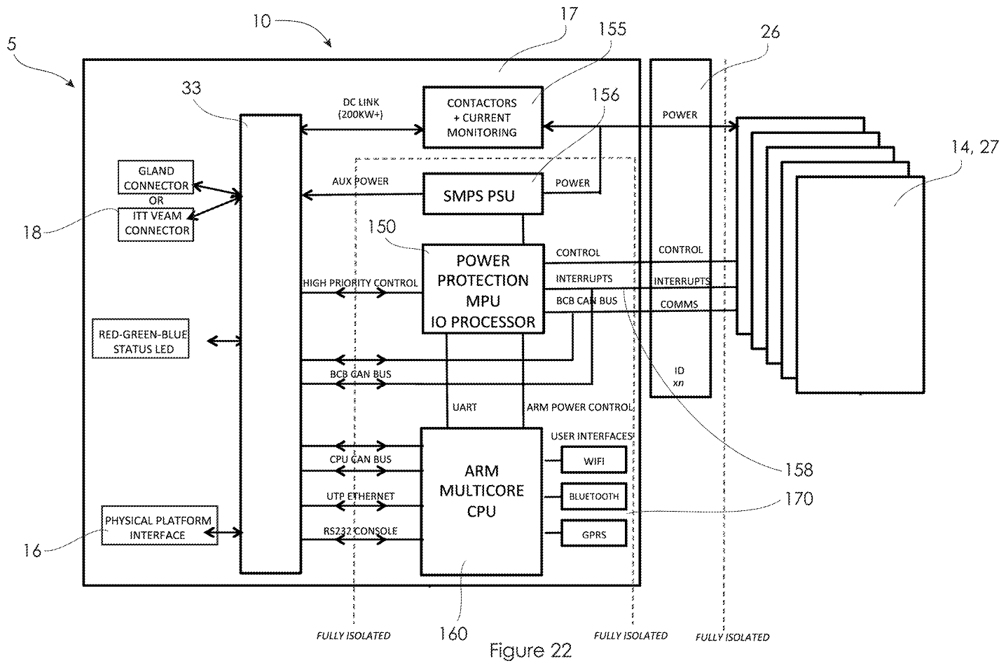

The clamping members 48, 50 are arranged in this example to provide clearance such as a space 88, best shown in FIGS. 21a and 22a, for sensors such as, for example, a current sensing part 90 that is fitted between the clamping members 48, 50 and the cell 32. In this example, the clamping members 48, 50 are L-shaped. However, other suitable shapes, such as rectangular, and other configurations may be used.

It is noted that the coupling or clamping arrangement 46 is preferably arranged to clamp the tabs 44 without bending or altering the tabs 44. This is advantageous as the cells 32 may remain as manufactured and the warranty may remain, which may be voided by welding or bending the tabs 44. Further, the contact surface between the tabs 44, clamping arrangement 46 and the printed circuit board 37 is arranged to conduct heat and transfer heat from the cells 32 into the printed circuit board 37.

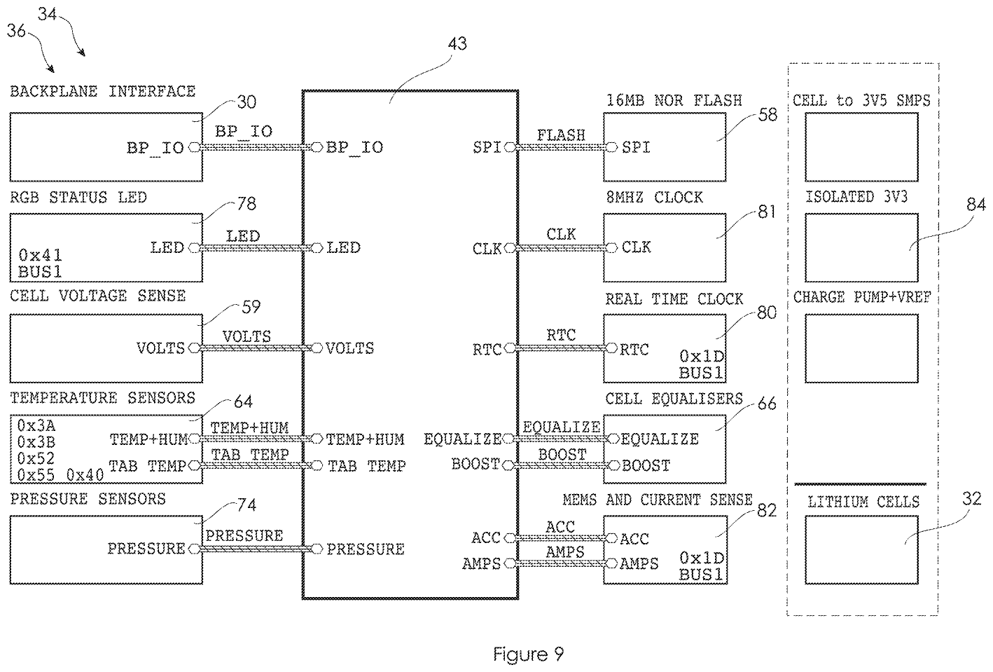

Turning to the cell carrier board 36 in more detail and referring more specifically to FIGS. 8b and 9, the cell carrier board 36 substantially carries the fully isolated control and sensor arrangement 34 including a micro controller or processor 43 that interfaces with one or more of: a press fit connector 30 (600A interface), Over Voltage Protection (OVP) and polyfused protection 57, a security ID 58 provided by an EEPROM device, a voltage sensor 59, a power supply unit 60, an RFID (Radio Frequency Identification Device) 62, cell temperature sensors 64, a boost equalisation chip 66, an open cell protection diode 68, an infrared and UV flame detection sensor 70, a 1 Mbps isolated communications bus 72, an FSR (Force Sense Resistor) pressure sensor 74, a humidity and temperature sensor 76, an RGB (Red-Green-Blue) status light 78, a real time clock 80, an 8 MHZ clock 81, a current core sensor 82, an isolated 3 kV DCDC converter 84 and shunt balancing 86. The board 36 has wings 79 that are arranged to slide into the guide slots 23 of the housing 12.

Accordingly, it should be appreciated that, for example, the control and sensor arrangement 34 is configured to monitor the status or condition of the cell carrier board 36, and in particular, physical condition properties such as the cell temperature and movement of the cell, (such as via the pressure sensor 74, and also monitor the electrical condition properties such as current. This allows the operating status of the cells 32 to be known rapidly before a failure event or even a fire may take place. Further, the control and sensor arrangement 34 provides self-condition monitoring is able to enter an alert or failure state when a condition, such as temperature, pressure or current, is outside of a specified operational condition range and, in the alert state, the control and sensor arrangement 34 may trigger isolation of its cell carrier board 36. The operational of the cell carrier board 36 is further detailed below.

Considering a selection of the components of the control and sensor arrangement 34 in more detail. The RGB status light 78, for example, allows a user to make a rapid visual assessment of each of the cell carrier boards 36 to determine its status such as being in service or perhaps have a fault. The pressure sensor 74 is arranged lengthwise alongside faces of battery cells 32 and this allows any expansion of the cell pouch to be detected that may indicate a compromised cell.

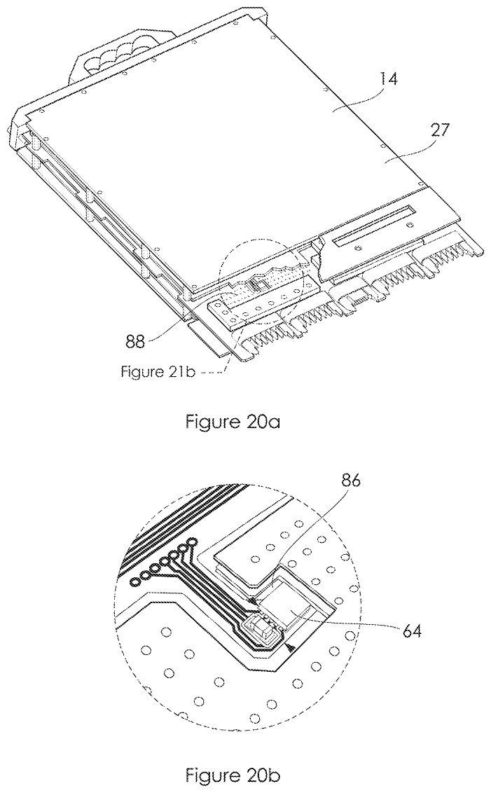

The cell temperature sensors 64 are configured to measure a temperature of one or more of the tabs 44 of the cells 32 to provide an indication of the inner temperature of the cell 32. As best shown in FIGS. 20a and 20b, due to the mechanical arrangement of the clamping arrangement 46, the space 86 is provided that allows the use of the cell temperature sensors 64, and in this case, the use of an optical, more specifically, infrared thermal sensor to directly measure the surface temperature of the relevant one or more of the tabs 44. This measurement is important because an increase in the cell temperature may indicate a failure or unsafe event.

The mechanical arrangement of the clamping arrangement 46 also provides clearance for a current sensing part 90 best shown in FIGS. 21a to 21c, that is provided in this example as a c-member 92 that extends about at least one of the tabs 44 of the cells 32. The c-member 92 is shaped to generate a current based on the Hall Effect and is in electrical communication with the current core sensor 82. This allows the current of the cell 32 to be monitored and, for example, allow the triggering of a current event that may, for example, be the triggering of the cell protection diode 68.

In more detail, the current monitoring circuit 66 monitors current going in and going out of the cell pouch, protects the cell from being overcharged, and protects the system from being over discharged. It is capable of identifying how effective battery equalisation is, by having the ability to monitor that the cell 32 is no longer subject to drawing current, which could result in the cell being overcharged.

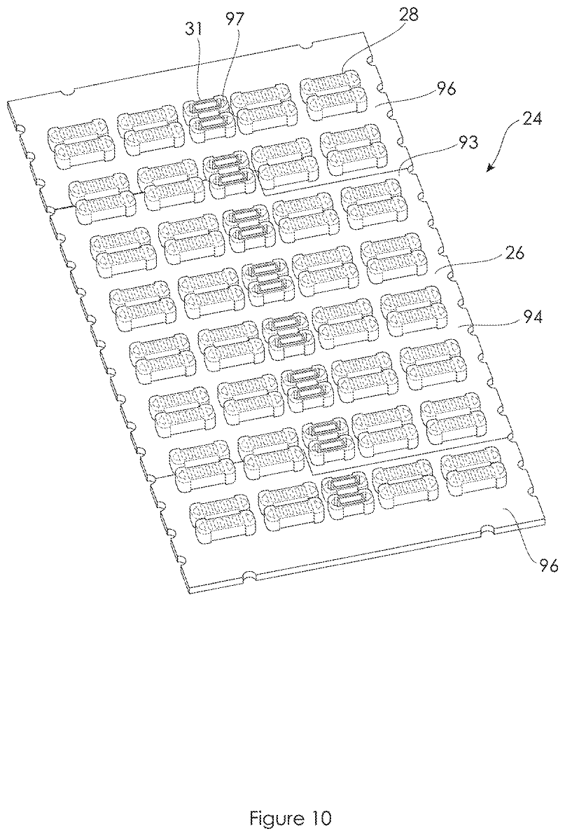

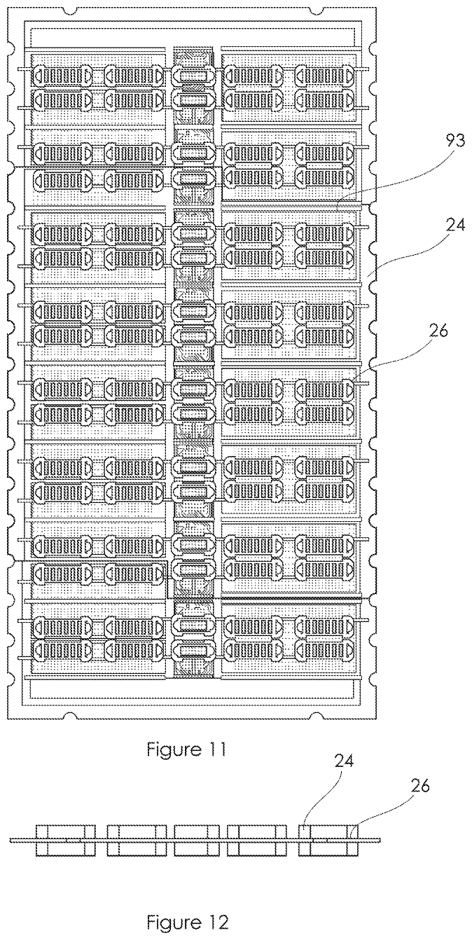

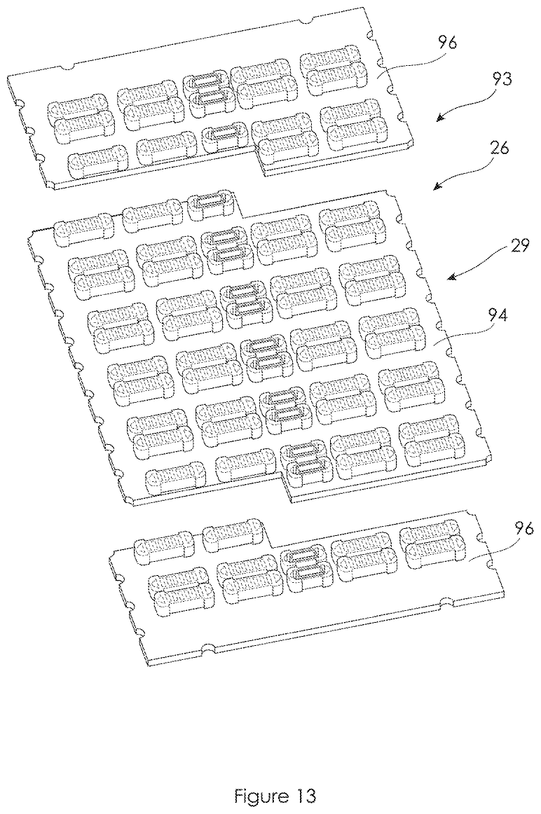

Referring now to FIGS. 10, 11, 12 the connection arrangement 24 is shown in more detail with the example connection board 26 being formed of a plurality of board sections 93 including an intermediate larger board 94 and two flanking smaller boards 96 that are reconfigurable and connectable to provide different sized boards to accompany changes in sizes of the housing 12. Each of the boards 94, 96 having electrical connectors and data ports for interfacing with the cell carrier boards 36 when fitted to the housing 12. The connection board 26 also includes identifiers 97, provided here in the form of EEPROM chips, that may be fitted at each of the connectors 31 associated with each of the slots to provide identification of the slots and identification of the carrier boards 36 when connected.

Accordingly, the boards 93 provide a scalable series of interconnects that are configurable to move power bi-directionally and provide communications. They provide isolation for multiple cells 32 in one enclosure, power connectivity to charge and discharge, and communications to either systems or groups of sub-systems, by a common method such as a jumpers to allow communications across selected multiple groups, to form one system or multiple sub-systems of either single or multiple batteries within one enclosure, using one battery connection board and housing. The user builds a unit depending on the amount of power required and configuration.

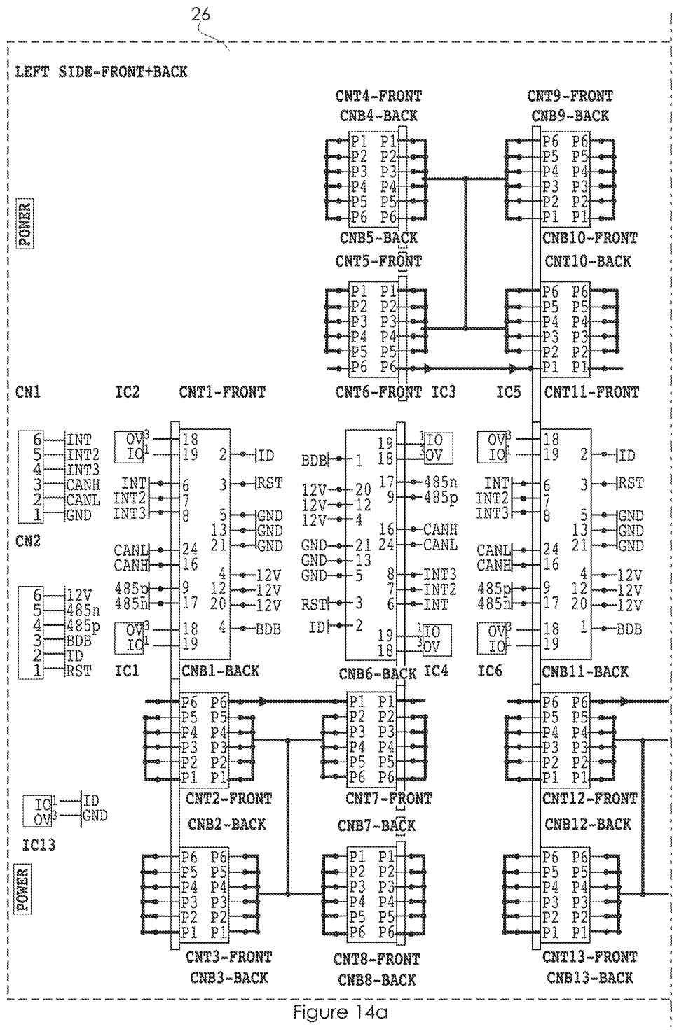

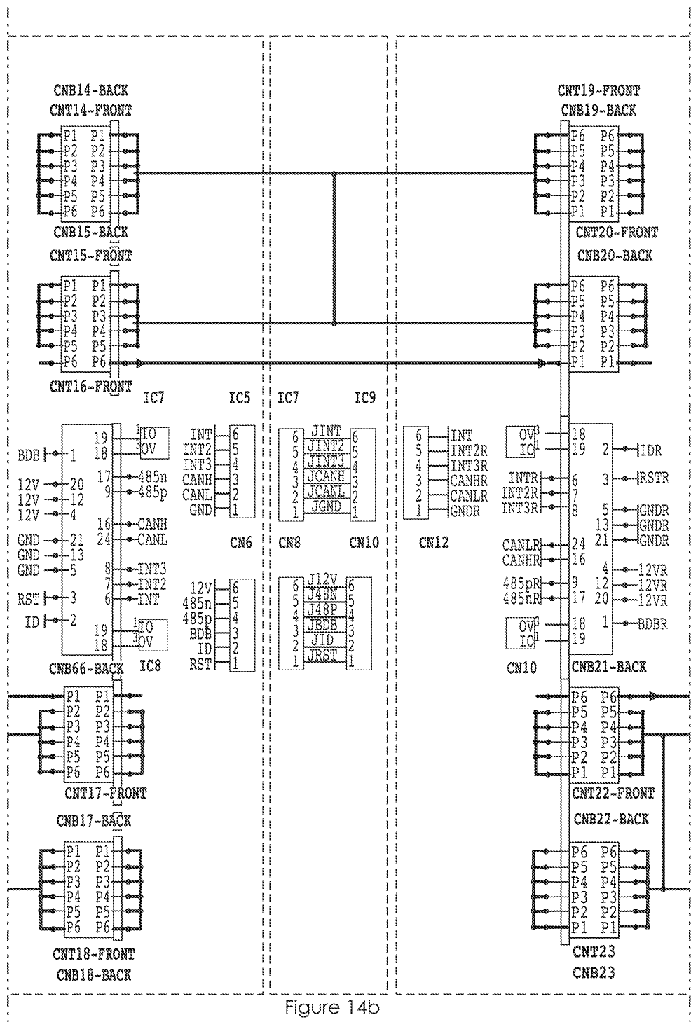

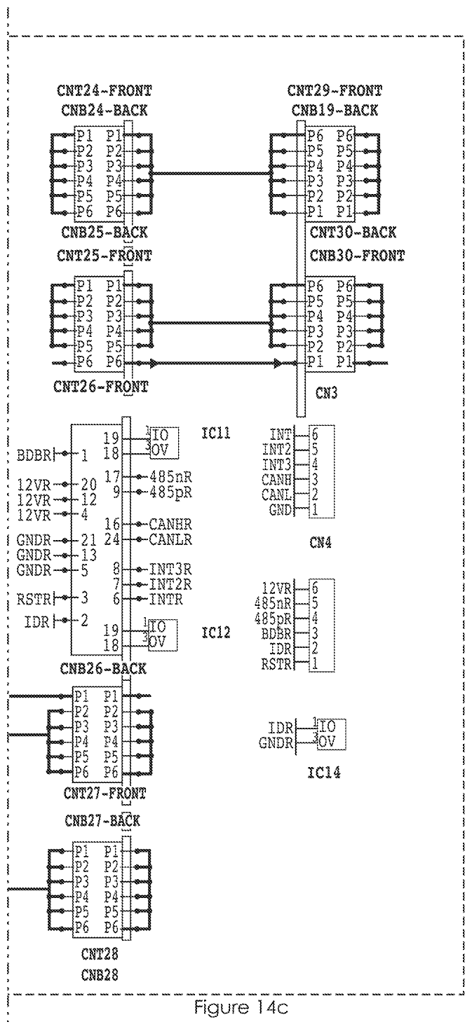

Referring to FIGS. 14a to 14c, there is shown an example circuit diagram of the connection board 26. It is noted the example circuit diagram is non-limiting and other circuits or configurations may be employed to provide a similar function. FIGS. 14a to 14c thereby illustrates a scalable component of the connection board 26.

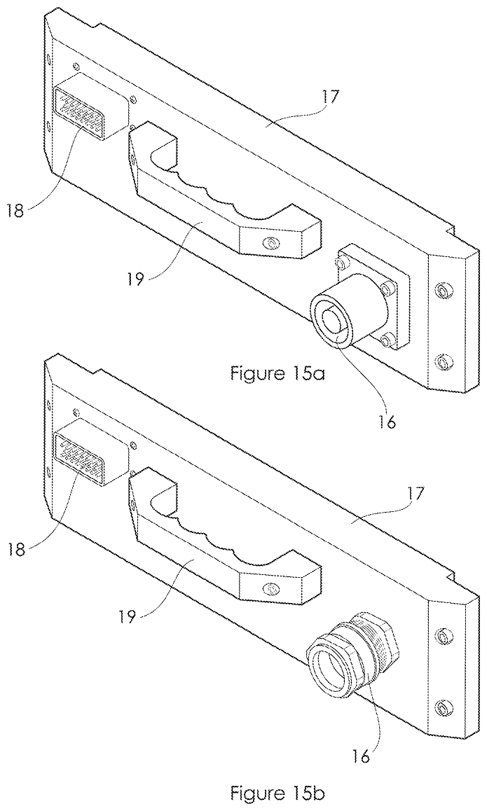

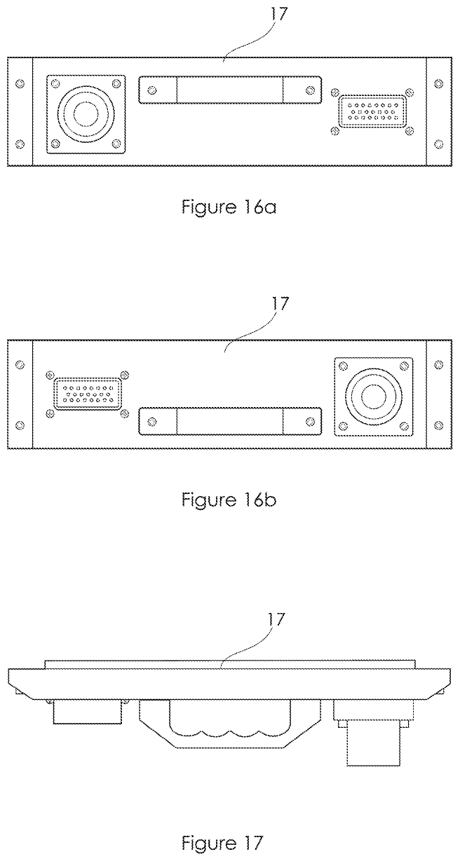

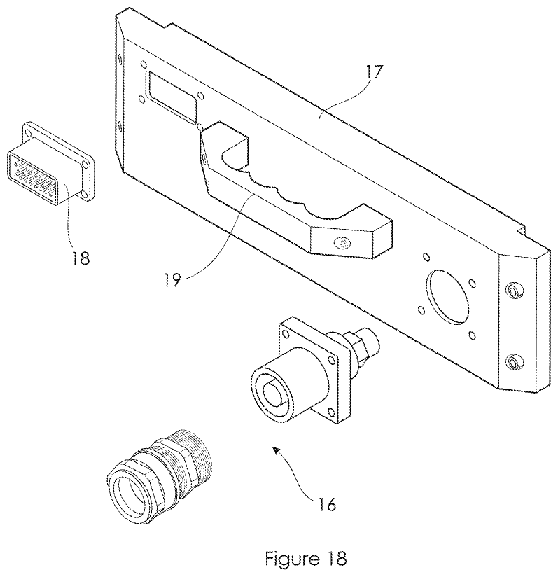

Referring to FIGS. 15a to 18, a front or heat sink block 33 of the battery interface board 17 that supports the handle 19. The battery interface board 17 provides a protected interface to the external environment and in this example includes the electrical connector port 16 and data port 18.

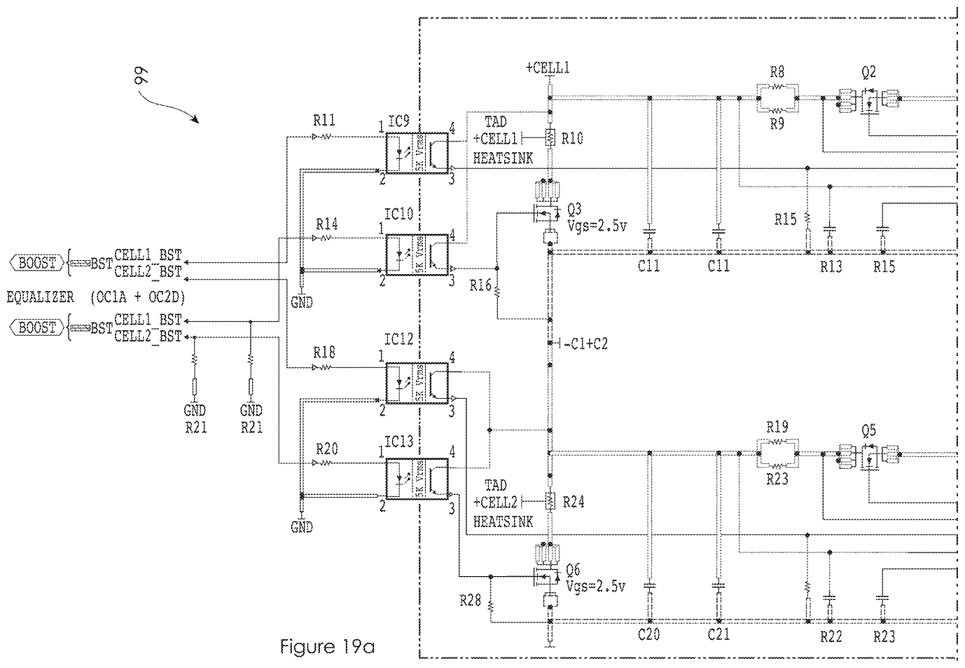

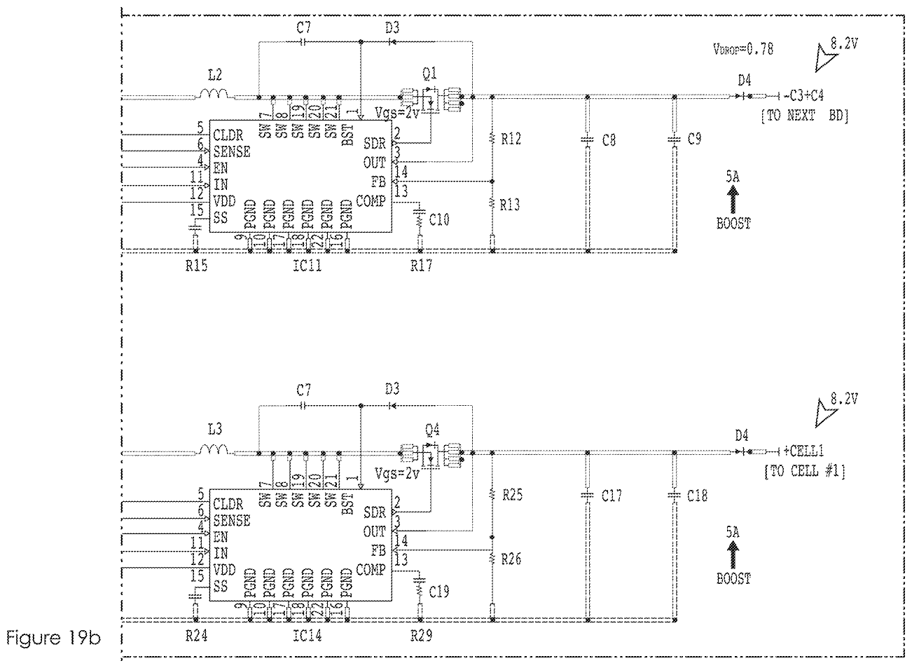

Referring to FIGS. 19a and 19b, there is provided an example of a cell equalisation circuit 110 of the cell boost equalisation chip 66 carried by each of the cell carrier boards 36. The cell boost equaliser functions to take excess power from fully charged cells that are exposed to being potentially compromised by excess charge, and transfer that power by boosting the potential, into the next cell where the charge is required. If that cell is fully charged also, then its booster boosts the potential again, where it is transferred up the cell array to batteries that do require charge, where the potential is then absorbed. It is noted that the shunt balances are part of the equaliser circuit which forms performs shunt and boost functions.

There are additional cell balancing circuits in this diagram in the form of classical resistor-based power burning circuitry, that is used to convert any excess energy into heat in order to maintain a voltage potential that prevents the cell from being subject to overcharge conditions. The chip 66 is configured to be capable of being turned on and off, by the local battery management system (BMS), is thermally and current-limit protected, and is precision voltage set to 1% of the charge requirements which may be, for example, 4.1 volts, but may be adjusted. Again, the example cell equalisation circuit is provided for example purposes only and is non limited, other forms of the circuits may be employed. The local battery management system (BMS) may be an external computer (not shown) in communication with the battery apparatus 10 via the interface boards 17.

Referring to FIG. 22, there is disclosed a block diagram of the system 5 showing the apparatus 10 and the overall arrangement of the cell carrier boards 36, battery connection boards 26 and battery interface boards 17. In this arrangement, it may be seen that the battery interface board 17 provides the master control between the cell carrier boards 36 and providing power to an external consumer, such as a motor or other equipment. The battery interface board 17 serves to manage and provide additional control of each of the cell carried boards 36 and ultimately provide an “interface” between an external device or environment and the cell carrier boards 36. The battery interface board 17 performs the task of power management, high level platform and user interface and overall system controller.

Turning to the battery interface board 17 in more detail, the battery interface board 17 may also be based on a printed circuit board (no shown) in a similar manner as the cell carrier board 36. The printed circuit board may support the front or heat sink block 33. The battery interface board 17 include a first microcontroller or processor 150 configured to communicate with each of the cell carrier boards 36 via the connection board 26 and second controller or processor 160 that is configured to communicate with the processor 150, and provide communication to an external environment such as to an external device or battery management system or interface (not shown). This enables the battery interface board 17, and any battery management system to, for example, monitor and control each of the cell carrier boards 36 individually, and, for example, determine the status of each of the cell 32 within each of the cell carrier boards 36. Accordingly, for example, an at fault battery arrangement 36 or cell 32 thereof may be identified, removed and replaced.

The battery interface board 17 further includes contactors 155, that may also be provided in the form of a switch or relay, and an external power source 156 to power the contactors 155. The contractors 155 are in communication with the cell carrier boards 36 which may trigger the contactors 155 as is detailed below to isolate one or more of the cell carrier boards 36. A status indicator 165 may also be provided.

The second controller or processor 160 may provide a wireless communication 170 interface such as via WIFI, Bluetooth, GRPS or other cellular network such as 4G or 5G. The second controller or processor 160 may also provide the physical user interface to communicate control signals to an external device, such as a battery management system or interface. For example, a user control panel of a

In more detail, the function of the interface board 17 includes the following functions: access to the array of cells 32 as a battery, as either a single group or with multiple interface boards 17 as multiple groups; processes output (specific regulated voltage, direct battery voltage, converted or inverted voltage AC-DC etc); processes the input (battery charge input); and communications (provides platform access to the specific battery, sub-group battery for configuration status monitoring and control) in the form of wired and wireless communications options. The interface board 17 removes the power from the array of cell carrier boards 36 in the form that the consumer of the power requires.

It is noted that there are two methods of identification “ID”. Firstly, each cell carrier board 36 plugs into a single slot of the connection board 26. The cell carrier board 36 provides a unique ID for that slot, allowing the carrier board 36 to identify itself with a unique ID that it can then share via the comms bus back to each interface board 17.

Secondly, there is also an additional ID system where each carrier board 36 has its own unique ID device, allowing the interface board 17 to read and identify each and every cell carrier board 36 plugged into a connection board 26 array. This allows for a full head count when operating communications over the shared bus, and for confirming all the cell carrier boards 36 are present and correct.

Turning now to methods of operation and use of the system 5, apparatus 10 and cell carrier boards 36 thereof, below are present three example operational scenarios to highlight some, but not all, of the advantageous functions of the system 5, apparatus 10, interface boards 17, and cell carrier boards 36.

### Example 1

The first example relates to a method for forming or configuration the battery system 5 including the battery apparatus 10 having an adaptively expandable capacity such as, for example, 48 Volts, 350 Volts, 700 Volts, etc.

The method includes selecting a system capacity and a selecting a number of the cell carrier boards 36, more specifically the cell carrier boards 36, to meet that capacity. Two of the battery interface boards 17, one positive and one negative are selected to interface with the selected cell carrier boards 36.

Next, the components of the housing 12 are selected and the connection board 26 is arranged to be provided within the housing 12. Examples of the housing 12 are shown in FIGS. 1 and 2, and FIGS. 4a and 4b. The connection board 26 is arranged to fit with the selected cell carrier board 36 and the interface boards 17.

The selected cell carrier boards 36 and the interface boards 17 may be then fitted into the respective locations in the housing 12. Typically, this will include the positive interface board 17 slotted within the positive most side of battery apparatus 10 and a negative interface board 17 slotted within the negative most side of battery apparatus 10, and one or more of the selected cell carrier boards 36 may slotted in between in any order.

It is noted that the identifiers 58, that may be EEPROM in this example, of the cell carrier boards 36 are typically associated with a relevant slot number either during manufacture or during assembly. This allows identification and confirmation of the location of each particular one of the cell carrier boards 36 within the stack.

It is also noted the respective controllers 43, 150 of the cell carrier boards 36 and the interface boards 17 should have been loaded and preconfigured with software and firmware, to operate the cell carrier boards 36 and the interface boards 17. In the methods described herein, it is the software and firmware that configures the respective controllers 43, 150 to carry out the respective steps.

The software of the interface boards 17 may be configured with individual capacity of the cell carrier boards 36 (e.g. 75 Ah, 80 Ah etc.), the number of cell carrier boards 36 within its pack as well as additional parameters identifying cell characteristics i.e. min/max voltage, min, max temperature, min/max current which defined the bounds of the operational conditions for the condition monitoring.

The system 5 may be powered on and an external controller (not shown) may communicate, such as via CAN (Control Area Network) to put the interface boards 17 into its configuration mode. The configuration mode enables the interface boards 17 to set the operational parameters of the cell carrier boards 36. This includes but is not limited to safety parameters such as voltage, current and temperature limits as well as application parameters such as cell carrier board 36 slot reporting number, cell balancing parameters and other diagnostic logging settings. The interface boards 17 may then turn on the cell carrier bards 36 through the connection board 26 and will wait for the cell carrier boards 36 to self-configure and begin reporting their status or condition.

The self-configuration routine of the cell carrier boards 36 may include communication with the identifier, in this example the 1WB EEPROM, associated with its specific slot number of the housing 12, to enable the cell carrier boards 36 to identify in which position it is within the pack. The cell carrier boards 36 may then each start communicating condition or status information, such as temperature or voltage, to the relevant interface boards 17.

In this mode, the interface boards 17 will be able to identify if a cell carrier board 36 has incorrectly identified itself by noting any slot numbers missing during CAN communication with cell carrier boards 36 through the interface boards 17. If a cell carrier board 36 has not been configured to report on its specific slot number it will report by default on a specific CAN ID. The interface boards 17 will then be able to associate the specific cell carrier board 36 to its correct ID. This feature may be important when replacing damaged cell carrier board 36 in a pack that is already in operation.

It is noted that the cell carrier boards 36 have a specific identifier, such as 1WD EEPROM, attached to them as well and the interface boards 17 and may interrogate these identifier devices even if the cell carrier boards 36 are turned off. This allows the interface boards 17 to determine which cell carrier board 36 device ID needs to be associated with a specific slot number. This enables the interface boards 17 to have awareness of exactly which slot each cell carrier boards 36 needs to be programmed with and can configure the individual cell carrier boards 36 to that specific slot.

Once the cell carrier boards 36 have all been initialised and are correctly reporting their status on the correct slot number. The interface boards 17 will be able to report back that the battery is setup.

The interface boards 17 will then calculate the minimum cell voltage and configure each cell carrier board 36 to begin balancing to that level. The balancing is described in further detail in relation to Example 2 below. Once balanced, the interface boards 17 report system ready for use.

### Second Example

Turning now to the second example method, a second example method is provided below which generally outlines the step of replacing or interchanging a removable one of the cell carrier board 36 from the battery apparatus 10 of the system 5.

The method may include connecting a device such as a mobile computing or computing device (not shown) to the battery apparatus 10 that can communicate to it via the CAN. This device will put the interface boards 17 into a configuration mode, referred to herein as a cell carrier board 36 interchange or swap mode. In the interchange or swap mode, the cell carrier board 36 at fault or to be changed can be physically identified and removed from the battery apparatus 10. The interface boards 17 will identify via CAN to the external device that the problem cell carrier board 36 has been removed as it will receive no messages on the CAN bus from that specific slot.

The replacement cell carrier board 36 preferably should be pre-charged higher than the lowest cell voltage of any cell carrier board 36 on the pack. The cell carrier board 36 is then replaced with the replacement cell carrier board 36. As described above in the first example, the new cell carrier board 36 should read its respective slot number via the indicator device, that may be an identification device, such as 1WB EEPROM, located on the connection board 26. However, in this example the interface board 17 may also take control and reconfigure the new cell carrier board 36 to its appropriate slot number. The method may include continuing the replacement step with each cell carrier board 36 that needs to be replaced.

Once cell carrier boards 36 have been identified the external device will then send a message to the interface board 17 with a signal to confirm that the cell replacement has been completed. Upon completion of this the interface board 17 will now balance all cells 32 down to the minimum cell voltage on the pack including the newly added cells as outlined below.

During balancing, the balancing circuit bleeds current through a resistor, that in this example may be a R500, which is controlled via a PWM (Pulse Width Modulation) signal from the microcontroller present on the cell carrier board 36.

By controlling the bleeding with the PWM signal, the battery apparatus 10 is able to adjust the level it can balance the cells 32 through software in the call carrier board 36. The combination of this bleed circuit with temperature sensor allows the software to maximise cell balancing whilst ensuring the cell balancing circuit 66 does not overheat. It starts off balancing at the fastest rate it can and as the cell temperature rises it will back off balancing down to, in this example, 400 mA.

Additionally, via component selection the cell carrier boards 36 are able to balance the cells at a higher rate, and even on the low end the battery interface board 17 can balance cells at 400 mA and at a maximum it can be done at 4A. Once the pack has been balanced, it will then be ready for use. It will communicate with the external CAN device that the battery apparatus 10 is ready for operation and the entire battery apparatus 10 will need to be power cycled.

### Third Example

The third example illustrates a method of how the system 5 identifies faults on the battery apparatus and will communicate a fault or alert condition with an external device or apparatus such as a vehicle or equipment. The fault or alert condition may indicate that a cell carrier board 36 of the battery apparatus 10 may need to be replaced.

The control and sensor arrangement 34 of each cell carrier board 36 including, more specifically the controller 43, is configured to manage each cell carrier board 36 independently. Accordingly, each cell carrier board 36 can manage itself and can self-identify if they have failed in a way that requires the cell carrier board 36 to need to be serviced or replaced. The main way this is identified is by monitoring the voltage and temperature of the cells. If cell voltage or temperature moves out of its regular operating range. The cell carrier board 36 can enable a NMI (Non-Masking Interrupt) line 56, as shown in FIG. 22, through to the interface board 17. This will disable the contactors on the interface board 17 into an open state. This will stop power flow out of the cell carrier board 36 and thereby isolate the cell carrier board 36.

In addition, the controller 150 of the interface board 17 may be configured to monitor all the cell carrier boards 36 within the pack can also identify if any of the cell carrier boards 36 and cells 32 thereof have moved out of their operating range. If this happen it will also open the contactors 155 using the NMI 158 and will send a signal to the system 5 via CAN with information indicating which cell carrier board 36 has failed and what the characteristics of the cells are.

Each interface board 17 contains persistent memory (not shown) and can keep track in memory of whether the battery apparatus 10 has been charging or discharging when the fault occurred, as well as the specific cells 32 of the cell carrier board 36 in the pack that raised the fault. In addition to this, the battery interface board 17 is configured to record keep a log of this data in memory and over time will be able to identify if a specific cell within the pack is continuously failing. If the battery runtime is excessively low and a specific cell continues to fail, then the interface board 17 can raise an error state or flag to the system 5 that the cells 32 or entire cell carrier board 36 may need to be replaced.

Advantageously, there has been described a configurable and modular battery system formed of one or more apparatuses that have of a plurality of cartridge style cell carrier boards. Each apparatus may be adapted in capacity by selecting a number of the cell carrier boards, referred also herein also as battery cartridges, and then forming the housing with the panels, connectors and connection board to suit.

The connection between the battery cartridges and the connection board of the housing is a press fit or “plug and play”, and this allows the battery cartridges to be easily connected, disconnected and replaced (swap out) without the use of complex tools (i.e. toolless), wires or welding.

Further advantageously, the battery cartridges include a coupling arrangement, in this example clamps, that secure to the tabs of the battery or battery cells, thereby not requiring welding that may void the cell manufacturer's warranty. Further, the clamps are positioned to allow direct or indirect sensing of the tabs, and in this example a current sensor is in position at one of the tabs and a thermal sensor at the other of the tabs. These sensors form part of a control and sensor arrangement carried by each of the battery cartridges which allow the status and function of each of the cells to be determined by the battery management system. The system being able to identify and control each inserted battery cartridges.

Further sensors include the pressure sensor and a flame/arc sensor, via infrared and ultraviolet light. Further still, a current bypass circuit is also provided that, for example, initiates a current bypass if the cell is in an unsafe state. The above electronic and sensor arrangement in combination with the cartridge style connection that allows individual monitoring allows the system to provide substantial performance, efficiency, and safety advantages. The system also provides the ability to pre-empt and provide the requirements to keep the system in service constantly with little to no downtime, and no requirement for logistics or capex-based service expenditure. The battery is an asset rather than a liability.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The reference in this specification to any known matter or any prior publication is not, and should not be taken to be, an acknowledgment or admission or suggestion that the known matter or prior art publication forms part of the common general knowledge in the field to which this specification relates.

While specific examples of the invention have been described, it will be understood that the invention extends to alternative combinations of the features disclosed or evident from the disclosure provided herein.

Many and various modifications will be apparent to those skilled in the art without departing from the scope of the invention disclosed or evident from the disclosure provided herein.

1. A battery apparatus including:
a housing with a connection arrangement;
a plurality of interoperable battery cartridges removably fittable to the housing to connect with the connection arrangement to form a stack, each of the interoperable battery cartridges including a carrier board supporting at least one battery cell and a battery control and sensor arrangement configured to monitor a condition of the at least one battery cell, and at least one carrier board connector adapted to connect with the connection arrangement;
at least one battery interface arrangement adapted to be removably fitted to the housing to connect with the connection arrangement so as to be in communication with a selection of the plurality of interoperable battery cartridges via the connection arrangement, the least one battery interface arrangement including an interface board supporting an interface control arrangement with an interface controller, and an associated power outlet and at least one interface board connector adapted to connect with the connection arrangement,
wherein the plurality of interoperable battery cartridges each have an associated unique identifier readable by the interface control arrangement to enable the interface control arrangement to operate with each of the selection of the plurality of interoperable battery cartridges to provide power therefrom at the power outlet.

2. The battery apparatus according to claim 1, wherein the battery control and sensor arrangement of each of the plurality of interoperable battery cartridges is configured to trigger an error event if the condition indicates an out of condition state.

3. The battery apparatus according to claim 2, wherein, in the error event, a triggered one of the plurality of interoperable battery cartridges is identifiable based on the unique identifier.

4. The battery apparatus according to claim 2, wherein, in the error event, the location of a triggered one of the plurality of interoperable battery cartridges is identifiable.

5. (canceled)

6. The battery apparatus according to claim 2, wherein the unique identifier is associated with operational conditions of each of the plurality of interoperable battery cartridges, and wherein the interface control arrangement is adapted to monitor the condition of each of the plurality of interoperable battery cartridges and trigger an error event if the condition is outside the operational conditions.

7. The battery apparatus according to claim 6, wherein in the error event, the interface control arrangement is adapted to isolate each triggered one of the plurality of interoperable battery cartridges.

8. The battery apparatus according to claim 7, wherein in the error event a contact associated with the interface control arrangement is moved to an open state to isolate triggered ones of the plurality of interoperable battery cartridges.

9. (canceled)

10. (canceled)

11. The battery apparatus according to claim 1, wherein the condition includes one or more of cell temperature, current, voltage and pressure.

12. (canceled)

13. The battery apparatus according to claim 1, wherein the connection arrangement includes location identifiers associated with positions within the stack, the location identifiers being readable by the control and sensor arrangement of the plurality of interoperable battery cartridges.

14. The battery apparatus according to claim 13, wherein the location identifiers provide a location of each of the plurality of interoperable battery cartridges within the stack.

15. The battery apparatus according to claim 1, wherein each of the plurality of interoperable battery cartridges includes an identification device in communication with the control and sensor arrangement to provide the unique identifier.

16. The battery apparatus according to claim 1, wherein the each of the plurality of interoperable battery cartridges identified by the unique identifier has an associated operational voltage, and the interface control arrangement is configured to read voltages associated with each of the plurality of interoperable battery cartridges and balance each of the plurality of interoperable battery cartridges to the operational voltage.

17. The battery apparatus according to claim 16, wherein the operational voltage is a lower most of the read voltages, with each of the plurality of interoperable battery cartridges being balanced to the lower most of the read voltages.

18. The battery apparatus according to claim 16, wherein the interface control arrangement is configurable with a pre-determined stack voltage, and is configured to tally the voltage of each of the plurality of interoperable battery cartridges to determine if a read stack voltage is equal to the pre-determined stack voltage.

19. (canceled)

20. (canceled)

21. The battery apparatus according to claim 1, wherein the connection arrangement and plurality of interoperable battery cartridges each include complementary connectors to allow for toolless connection thereof.

22. The battery apparatus according to claim 1, wherein the housing includes an open side, a base and a top, and the connection arrangement is provided in the form of a connection board being fitted in an orientation between the base and the top of the housing, and spaced apart from the open side so as to define a space in which the plurality of interoperable battery cartridges are insertable.

23. The apparatus according to claim 21, wherein the connection board and the plurality of interoperable battery cartridges are adapted to have a press fit connection thereby allowing toolless fitting of the plurality of interoperable battery cartridges.

24. The apparatus according to claim 23 wherein each of the plurality of interoperable battery cartridges includes a handle arranged to allow a user to insert and withdraw each of the plurality of interchangeable battery cartridges from the housing.

25. (canceled)

26. A battery apparatus including:
a housing with a connection board,
at least one cell carrier board adapted to be removably fitted to the housing to connect with the connection board, the at least one cell carrier board including at least one battery cell and a circuit board with a battery control and sensor arrangement including a controller configured to monitor a condition of the at least one battery cell and at least one carrier board connector adapted to connect with the connection board,
at least one battery interface board adapted to be removably fitted to the housing to connect with the connection board so as to be in communication with the at least one cell carrier board via the connection board, the battery interface board including an interface circuit board with an interface control arrangement including an interface controller configured to monitor the condition of the at least one battery cell, and an associated power outlet and at least one interface board connector adapted to connect with the connection board;
wherein the battery control and sensor arrangement is configured to trigger isolation of the at least one cell carrier board if the condition indicates a failure state.

27.-53. (canceled)

54. A battery apparatus including:
a housing with a connection arrangement;
a plurality of interoperable battery cartridges removably fittable to the housing to connect with the connection arrangement to form a stack, each of the interoperable battery cartridges supporting at least one battery cell and having at least one connector adapted to connect with the connection arrangement;
a battery control and sensor arrangement associated with the at least one battery cell configured to monitor a condition of the at least one battery cell;
at least one battery interface arrangement adapted to be fitted to the housing to connect with the connection arrangement so as to be in communication with a selection of the plurality of interoperable battery cartridges via the connection arrangement, the least one battery interface arrangement including an interface control arrangement with an interface controller, and an associated power outlet and at least one interface connector adapted to connect with the connection arrangement,
wherein the plurality of interoperable battery cartridges each have an associated unique identifier readable by the interface control arrangement to enable the interface control arrangement to operate with each of the selection of the plurality of interoperable battery cartridges to provide power therefrom at the power outlet.
